(19) United States
(12) Patent Application Publication
(10) Pub. No.: US 2012/0188733 A1
(43) Pub. Date: Jul. 26, 2012

(54) SUBSTRATE MOUNTING STRUCTURE, DISPLAY DEVICE EQUIPPED THEREWITH, AND SUBSTRATE MOUNTING METHOD

(75) Inventors: Hiroki Miyazaki, Osaka (JP); Gen Nagaoka, Osaka (JP); Yasuhiro Hida, Osaka (JP)

(73) Assignee: SHARP KABUSHIKI KAISHA, Osaka (JP)

(21) Appl. No.: 13/499,109

(22) PCT Filed: May 14, 2010
(86) PCT No.: PCT/JP2010/058172

§ 371 Date: Mar. 29, 2012

(30) Foreign Application Priority Data
Oct. 5, 2009 (JP) 2009-231177

(51) Int. Cl. H05K 7/06; B32B 37/12; H05K 1/16

(52) U.S. Cl. 361/760; 174/260; 156/60

(57) ABSTRACT

To provide a substrate mounting structure with which reliability can be improved. This substrate mounting structure includes an ACF (2) disposed on a surface (1a) of a glass substrate (1) and SMDs (3) mounted on the surface (1a) of the glass substrate (1) via the ACF (2) and disposed in an SMD mounting region (10a) on the surface (1a) of the glass substrate (1). Then, dummy components (4) are respectively disposed in a region adjacent to one side of the SMD mounting region (10a) and in a region adjacent to the other side thereof.

### TECHNICAL FIELD

The present invention relates to a substrate mounting structure, a display device equipped therewith, and a substrate mounting method.

### BACKGROUND ART

A technique for mounting an electronic component such as an IC chip on a surface of a substrate using an adhesive material for pressure bonding has been known in the past (for example, see Patent Document 1). A conventional substrate mounting method will be briefly described below.

As a conventional substrate mounting method, a film-form pressure-bonding adhesive material (thermosetting adhesive material) is first disposed on a surface of a substrate. Then, an electronic component is disposed on the surface of the substrate via this pressure-bonding adhesive material.

Next, heat is applied to a prescribed pressing member, and the electronic component is pressed toward the surface of the substrate by the heated pressing member. At this point, because heat is applied to the pressure-bonding adhesive material, the pressure-bonding adhesive material is hardened. That is, a state is created in which the electronic component is thermocompression-bonded to (mounted on) the surface of the substrate via the hardened pressure-bonding adhesive material.

Incidentally, an elastic body composed of rubber or the like is used as the pressing member used in a thermocompression bonding step in a conventional substrate mounting method. The reason for using such an elastic body in a thermocompression bonding step is to compensate for a difference in the heights of electronic components in cases where a plurality of electronic components with mutually different heights are simultaneously thermocompression-bonded to a surface of a substrate.

### RELATED ART DOCUMENTS

### Patent Documents

Patent Document 1: Japanese Patent Application Laid-Open Publication No. 2005-32952

### SUMMARY OF THE INVENTION

### Problems to be Solved by the Invention

However, in the aforementioned conventional substrate mounting method, when a plurality of electronic components are simultaneously thermocompression-bonded to the surface of a substrate, a disadvantage arises in that the electronic components are shifted from the desired positions.

For example, as is shown in FIG. 18, in cases where two electronic components 103 are simultaneously thermocompression-bonded to a surface 101a of a substrate 101 via a pressure-bonding adhesive material 102, when these two electronic components 103 are pressed toward the surface 101a of the substrate 101 by a pressing member (elastic body) 112, the balance of the pressing forces applied to the electronic components 103 from horizontal directions (directions parallel to the surface 101a of the substrate 101) is lost. In concrete terms, the pressing forces (arrows F1) applied to the electronic components 103 from the area between the adjacent electronic components 103 and the pressing forces (arrows F2) applied to the electronic components 103 from the open spaces end up being different in magnitude. For this reason, the positional shifting of the electronic components 103 occurs toward the open spaces.

The aforementioned disadvantage arises with the conventional substrate mounting method, so the resulting problem is that reliability is lowered.

The present invention was devised in order to solve the aforementioned problem, and an object thereof is to provide a substrate mounting structure, a display device, and a substrate mounting method which can increase reliability.

### Means for Solving the Problems

In order to achieve the object described above, the substrate mounting structure according to a first aspect of the present invention includes a substrate; a pressure-bonding adhesive material disposed on a surface of the substrate; and an electronic component mounted on the surface of the substrate via the pressure-bonding adhesive material and disposed in a first region of a surface area of the substrate. Furthermore, prescribed objects are respectively disposed in a second region adjacent to one side of the first region and in a third region adjacent to the other side of the first region which is opposite from this one side so that the electronic component is sandwiched by these prescribed objects.

In the substrate mounting structure according to the first aspect, by virtue of the configuration as described above, it is possible to suppress the positional shifting of the electronic component in horizontal directions (directions parallel to the surface of the substrate) during a mounting step in which the electronic component is mounted on the surface of the substrate. This effect will be described in detail below. Note that the mounting of the electronic component on the surface of the substrate is performed by disposing the electronic component on the surface of the substrate via the pressure-bonding adhesive material (e.g., thermosetting adhesive material) and then pressing the electronic component toward the surface of the substrate with a pressing member (elastic body), thus thermocompression bonding the electronic component to the surface of the substrate.

Specifically, in the substrate mounting structure according to the first aspect, in a state in which the electronic component disposed in the first region is sandwiched by the prescribed objects, this electronic component disposed in the first region can be pressed by the pressing member during the mounting step. Therefore, when the electronic component in the first region is pressed by the pressing member, the pressing force applied to the electronic component in the first region from the side of the second region (pressing force from a portion of the pressing member that has entered between the electronic component in the first region and the prescribed object in the second region) and the pressing force applied to the electronic component in the first region from the side of the third region (pressing force from a portion of the pressing member that has entered between the electronic component in the first region and the prescribed object in the third region) become substantially the same. Consequently, the positional shifting of the electronic component disposed in the first region in horizontal directions is suppressed.

Here, for instance, in cases where no prescribed object is disposed in one of the second region and the third region (e.g., second region) and a prescribed object is disposed only in the other of the second region and the third region (e.g., third region), a state is created in which there is an open space on the side of the second region as seen from the electronic component in the first region, and there is a prescribed object on the side of the third region. Therefore, the balance between the pressing force applied to the electronic component in the first region from the side of the second region and the pressing force applied to the electronic component in the first region from the side of the third region is lost, so the electronic component in the first region ends up positionally shifted in a horizontal direction (direction toward the second region). In such cases, a similar disadvantage arises whether the number of the electronic components disposed in the first region is one or plural.

Moreover, in cases where no prescribed object is disposed in the second region nor in the third region and a plurality of electronic components are disposed in the first region (arranged from the side of the second region toward the third region), if attention is focused on one of the electronic components located at the row ends in the electronic component row, a state is created in which there is an open space on the outside (on the second region side or on the third region side) as seen from this electronic component at an end of the row, while there is another electronic component on the other side of this electronic component. Therefore, the balance between the pressing force applied to the electronic component at the row end from the outside (the second region side or the third region side) and the pressing force applied to the electronic component at the row end from the opposite side thereof is lost, so the electronic component at the end of the row ends up positionally shifted in a horizontal direction (direction toward the second region or third region). Note that the disadvantage in such cases does not arise if the number of the electronic components disposed in the first region is one.

Thus, with the substrate mounting structure according to the first aspect, it is possible to suppress the positional shifting of the electronic components mounted on the surface of the substrate, thus making it possible to improve reliability.

In the substrate mounting structure according to the aforementioned first aspect, at least the prescribed object disposed in the second region is preferably a dummy component. By adopting such a configuration, the positional shifting of the dummy component occurs in a horizontal direction, but because the dummy component is a component that is not electrically connected to another component, there is no effect on the reliability.

In the substrate mounting structure according to the aforementioned first aspect, the prescribed object disposed in the third region may be a dummy component and may also be an electronic component different from the electronic component disposed in the first region. Furthermore, this prescribed object may also be an opposite substrate disposed so as to face the substrate.

In the substrate mounting structure according to the aforementioned first aspect, when among directions parallel to the surface of the substrate, a direction from the side of the second region toward the third region is taken as a first direction, a plurality of electronic components may also be arranged in the first region along the first direction.

In addition, when among directions parallel to the surface of the substrate, a direction perpendicular to the first direction is taken as a second direction, a plurality of electronic components may also be arranged in the first region in a matrix along the first direction and second direction. In this case, it is preferable that prescribed objects be further respectively disposed in a pair of regions adjacent to the first region in the second direction. If such a configuration is adopted, it is possible to suppress the positional shifting of the plurality of electronic components disposed in the first region in the first direction and also to suppress the positional shifting of the plurality of electronic components disposed in the first region in the second direction.

In the substrate mounting structure according to the aforementioned first aspect, the pressure-bonding adhesive material is preferably an anisotropic conductive film. By adopting such a configuration, it is possible to mount the electronic component(s) easily on the surface of the substrate.

The display device according to a second aspect of the present invention includes the substrate mounting structure according to the aforementioned first aspect. Such a configuration makes it possible to easily improve the reliability of the substrate mounting structure within the display device.

The substrate mounting method according to a third aspect of the present invention includes: preparing a substrate and disposing a pressure-bonding adhesive material on a surface of the substrate; disposing an electronic component in a first region of a surface are of the substrate via the pressure-bonding adhesive material; and thermocompression bonding the electronic component in the first region by pressing the electronic component toward the surface of the substrate with a pressing member. Furthermore, this substrate mounting method further includes, prior to the step of thermocompression bonding the electronic component in the first region, respectively disposing prescribed objects in a second region adjacent to one side of the first region and in a third region adjacent to the other side of the first region which is opposite from the one side, and when the electronic component is thermocompression-bonded in the first region, the electronic component and the prescribed objects are simultaneously pressed toward the surface of the substrate by the pressing member.

With the substrate mounting method according to the third aspect, as a result of the electronic component being mounted on the surface of the substrate through the aforementioned steps, the positional shifting of the electronic component in horizontal directions can be suppressed, so reliability can be improved.

In the substrate mounting method according to the aforementioned third aspect, it is more preferable that at least the prescribed object disposed in the second region be a dummy component.

In the substrate mounting method according to the aforementioned third aspect, it is more preferable that the interspace between the prescribed object disposed in the second region and the electronic component disposed in the first region and the interspace between the prescribed object disposed in the third region and the electronic component disposed in the first region be set to be the same size. If such a configuration is adopted, the pressing force applied to the electronic component in the first region from the side of the second region and the pressing force applied to the electronic component in the first region from the side of the third region can be made substantially the same.

### Effects of the Invention

Thus, with the present invention, it is possible to easily improve reliability.

### BRIEF DESCRIPTION OF THE DRAWINGS

FIG. 1 is a plan view of the substrate mounting structure according to a first embodiment.

FIG. 2 is a sectional view along line 100-100 in FIG. 1.

FIG. 3 is a sectional view for illustrating the substrate mounting method according to the first embodiment.

FIG. 4 is a sectional view for illustrating the substrate mounting method according to the first embodiment.

FIG. 5 is a diagram showing the forces that an electronic component receives during the mounting step.

FIG. 6 is a diagram showing the forces that electronic components receive during the mounting step.

FIG. 7 is a diagram showing the forces that electronic components receive during the mounting step.

FIG. 8 is a plan view of the substrate mounting structure according to a modified example of the first embodiment.

FIG. 9 is a plan view of the substrate mounting structure according to a modified example of the first embodiment.

FIG. 10 is a diagram for illustrating the results of an experiment performed in order to confirm the effects of the first embodiment.

FIG. 11 is a diagram for illustrating the results of an experiment performed in order to confirm the effects of the first embodiment.

FIG. 12 is a plan view of the substrate mounting structure according to a second embodiment.

FIG. 13 is a plan view of the substrate mounting structure according to a third embodiment (an enlarged view of a portion of the liquid crystal display panel of a liquid crystal display device).

FIG. 14 is a sectional view for illustrating the substrate mounting method according to the third embodiment.

FIG. 15 is a plan view for illustrating the substrate mounting structure according to a fourth embodiment (an enlarged view of a portion of the liquid crystal display panel of a liquid crystal display device).

FIG. 16 is a sectional view for illustrating the substrate mounting method according to the fourth embodiment.

FIG. 17 is a plan view of the substrate mounting structure according to a modified example of the fourth embodiment.

FIG. 18 is a sectional view for illustrating a conventional substrate mounting method (a diagram showing the forces that electronic components receive during the mounting step).

### DETAILED DESCRIPTION OF EMBODIMENTS

### First Embodiment

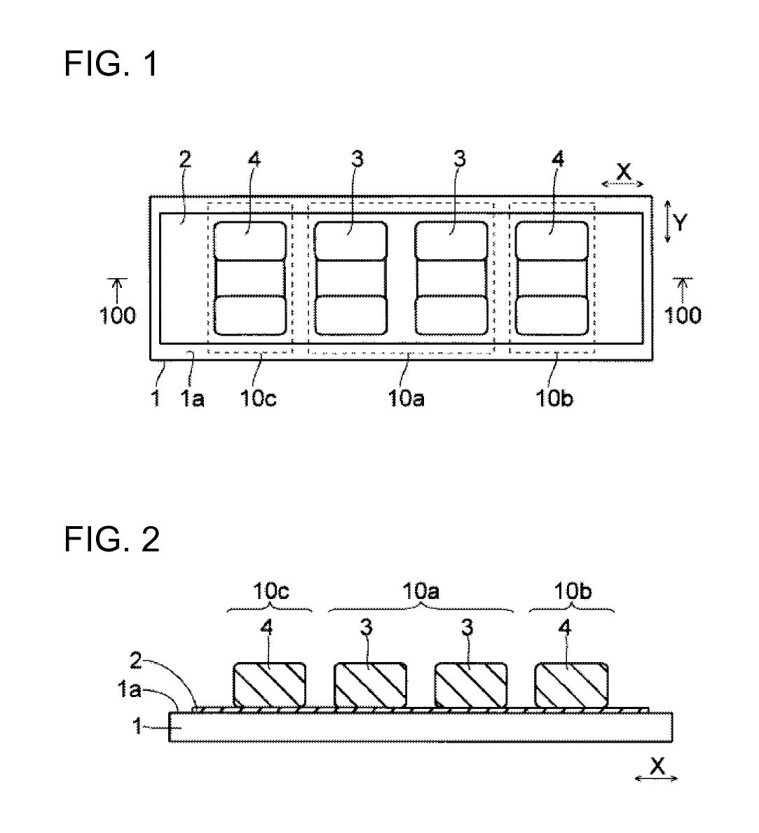

The substrate mounting structure according to a first embodiment will be described below with reference to FIGS. 1 and 2.

In the first embodiment, a glass substrate 1 having connection terminals (not illustrated) on a surface 1a is used. Note that the glass substrate 1 is one example of the “substrate” of the present invention, and a PWB (Printed Wiring Board), FPC (Flexible Printed Circuit), or the like may also be used.

An ACF (Anisotropic Conductive Film) 2 which is a pressure-bonding adhesive material (thermosetting adhesive material) is disposed on the surface 1a of the glass substrate 1. This ACF 2 is composed of a thermosetting resin having conductive particles mixed therein and has conductive properties with respect to a direction perpendicular to the surface 1a of the glass substrate 1 while having insulation properties with respect to directions parallel to the surface 1a of the glass substrate 1 (directions including the X direction and Y direction). Note that the X direction is a direction from the side of a dummy component mounting region 10b (described later) toward the side of a dummy component mounting region 10c (described later), while the Y direction is a direction perpendicular to the X direction.

Furthermore, an SMD (Surface Mount Device) 3 is mounted on the surface 1a of the glass substrate 1 via the ACF 2. That is, the SMD 3 is firmly fixed to the surface 1a of the glass substrate 1 by the ACF 2. Note that the SMD 3 is one example of the “electronic component” of the present invention, and examples include a resistor, capacitor, diode, and the like.

A plurality (e.g., two) of these SMDs 3 are present and are disposed on the surface 1a of the glass substrate 1 in a prescribed region 10a thereof, being lined up along the X direction. Note that the prescribed region 10a is one example of the “first region” of the present invention and is referred to as the SMD mounting region 10a in the following description.

Here, in the first embodiment, dummy components 4 that are not electrically connected to another component are also mounted on the surface 1a of the glass substrate 1 via the ACF 2 in addition to the SMDs 3. In concrete terms, a region adjacent to one side of the SMD mounting region 10a in the X direction and a region on the other side thereof (on the side opposite from the one side) respectively constitute dummy component mounting regions 10b and 10c in which the dummy components 4 are respectively mounted. Then, one dummy component 4 is disposed in each of the dummy component mounting regions 10b and 10c. That is, in the first embodiment, a state is created in which the two SMDs 3 are sandwiched between the two dummy components 4. Note that the dummy components 4 are one example of the “prescribed objects” of the present invention. Moreover, the dummy component mounting regions 10b and 10c are examples of the “second region” and “third region,” respectively, of the present invention.

The dummy components 4 that are disposed respectively in the dummy component mounting regions 10b and 10c are composed of components of the same structure as the SMDs 3. That is, resistors, capacitors, diodes, or the like are used as the dummy components 4. Note that the SMDs 3 and the dummy components 4 are preferably the same components with respect to each other, but these may also be different components from each other. In addition, in cases where the cost is taken into account, it is preferable that resistors which are inexpensive components be used as the dummy components 4.

The substrate mounting structure according to the first embodiment is configured as described above. Furthermore, this substrate mounting structure is manufactured through the following manufacturing process:

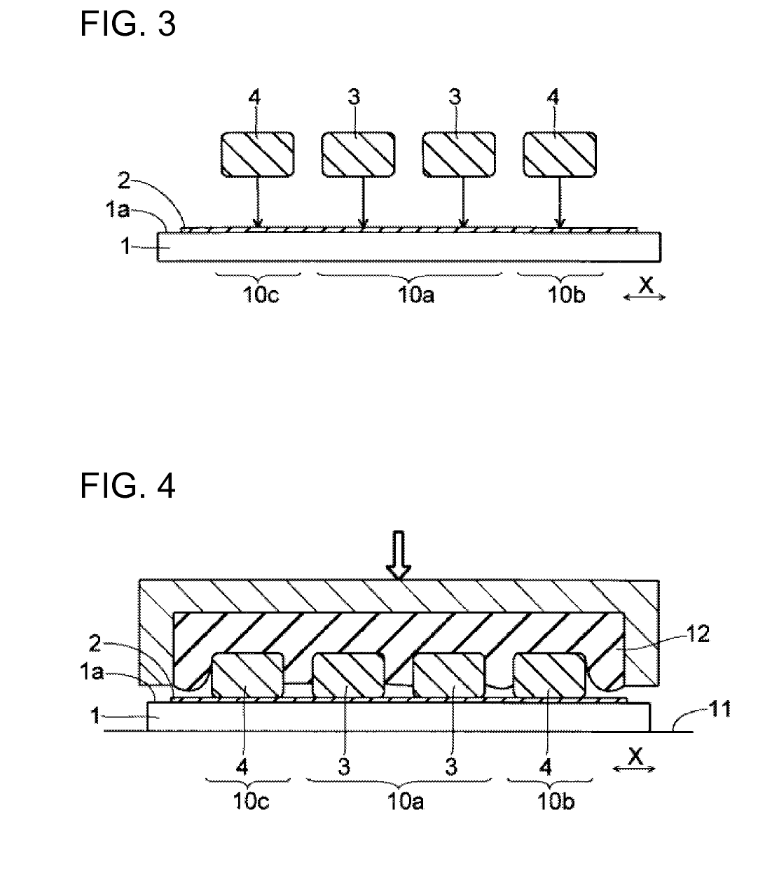

Specifically, as is shown in FIG. 3, first, a glass substrate 1 is prepared, and an ACF 2 is disposed on a surface 1a of this glass substrate 1. Moreover, SMDs 3 and dummy components 4 are disposed on the ACF 2. Thus, a state is created in which the SMDs 3 and dummy components 4 are disposed on the surface 1a of the glass substrate 1 via the ACF 2.

In this case, in the first embodiment, two SMDs 3 are disposed in the SMD mounting region 10a, and one dummy component 4 each is disposed in each of the dummy component mounting regions 10b and 10c that are adjacent to this SMD mounting region 10a in the X direction. In addition, these four components (two SMDs 3 and two dummy components 4) are lined up in a single row so as to mutually face the same direction and also so as to have equally-spaced intervals along the X direction.

Then, as is shown in FIG. 4, the glass substrate 1 is placed on a pressure-bonding stage 11, and heat is applied to an elastic body (e.g., rubber) 12 used as the pressing member. Subsequently, the SMDs 3 and dummy components 4 are simultaneously pressed by this heated elastic body 12 toward the surface 1a of the glass substrate 1.

At this point, the ACF 2 is heated and is therefore hardened in a state in which this ACF 2 is tightly adhered to the surface 1a of the glass substrate 1 and the SMDs 3 and dummy components 4. That is, the SMDs 3 and dummy components 4 are thermocompression-bonded to (mounted on) the surface 1a of the glass substrate 1 via the ACF 2. As a result, the substrate mounting structure of the first embodiment shown in FIGS. 1 and 2 is obtained.

Note that if the aforementioned manufacturing method is used, there is a risk of the mounting components being shifted significantly from the desired positions depending on the number of the mounting components to be mounted during the thermocompression bonding step (step shown in FIG. 4).

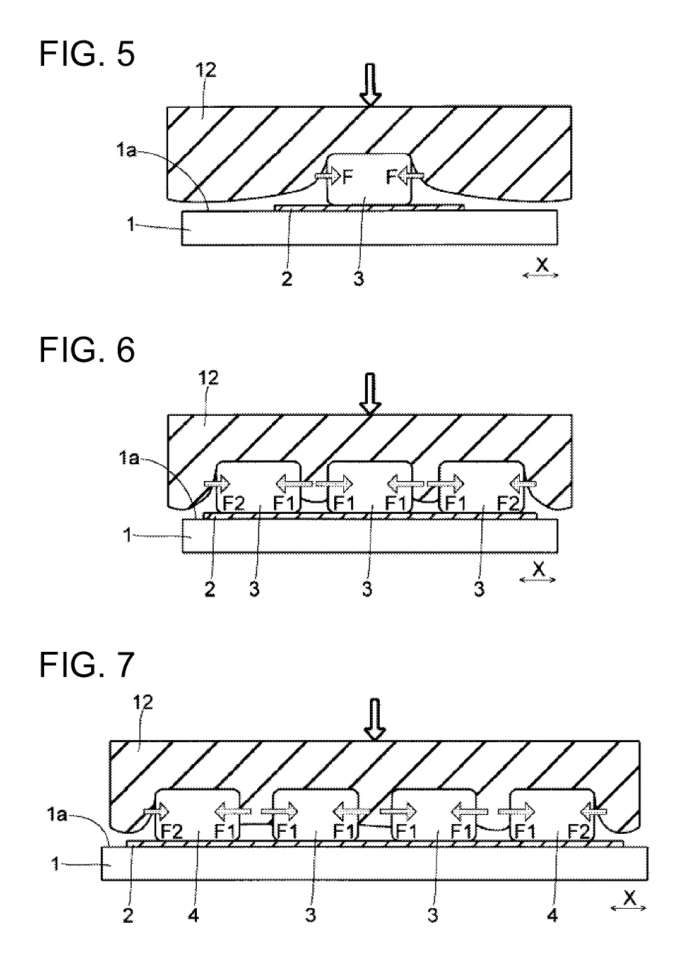

For example, in cases where there is one SMD 3 as the mounting component, with no other mounting components nearby as shown in FIG. 5, the pressing forces (arrows F) applied in horizontal directions (direction parallel to the surface 1a of the glass substrate 1) to the SMD 3 from the elastic body 12 become substantially uniform with respect to each other. Therefore, the positional shifting of the SMD 3 in horizontal directions is small in such cases.

Meanwhile, in cases where a plurality of (e.g., three) SMDs 3 are lined up in a single row in the X direction as shown in FIG. 6, the pressing forces in horizontal directions applied to the SMDs 3 from the elastic body 12 become non-uniform. In concrete terms, when attention is focused on the SMDs 3 located at both ends of the row, the pressing forces (arrows F1) applied to the SMDs 3 from the areas between adjacent SMDs 3 and the pressing forces (arrows F2) applied to the SMDs 3 from the open spaces are different in magnitude. For this reason, the SMDs 3 located at both ends of the row are respectively positionally shifted in a significant way in horizontal directions (directions toward the open spaces). However, with regard to the SMD 3 located in the middle of the row, the positional shifting in horizontal directions is small.

Furthermore, in cases where the number of mounting components to be mounted is two (see FIG. 18) or four or more as well, similar positional shifting inevitably occurs.

When these are taken into account, with the aforementioned configuration of the first embodiment (see FIG. 7), it can be said that because a plurality of mounting components (two SMDs 3 and two dummy components 4) are lined up in a single row in the X direction, for the two mounting components located at both ends of the row, the positional shifting in horizontal directions inevitably becomes large. However, the two mounting components located at both ends of the row are dummy components 4 in the first embodiment, so although the positions of the dummy components 4 are inevitably shifted significantly in horizontal directions, for the SMDs 3 located toward the middle of the row, the positional shifting in horizontal directions is small.

In the first embodiment, by adopting the configuration as described above, it is possible to suppress the positional shifting of the SMDs 3 mounted on the surface 1a of the glass substrate 1, so reliability can be improved.

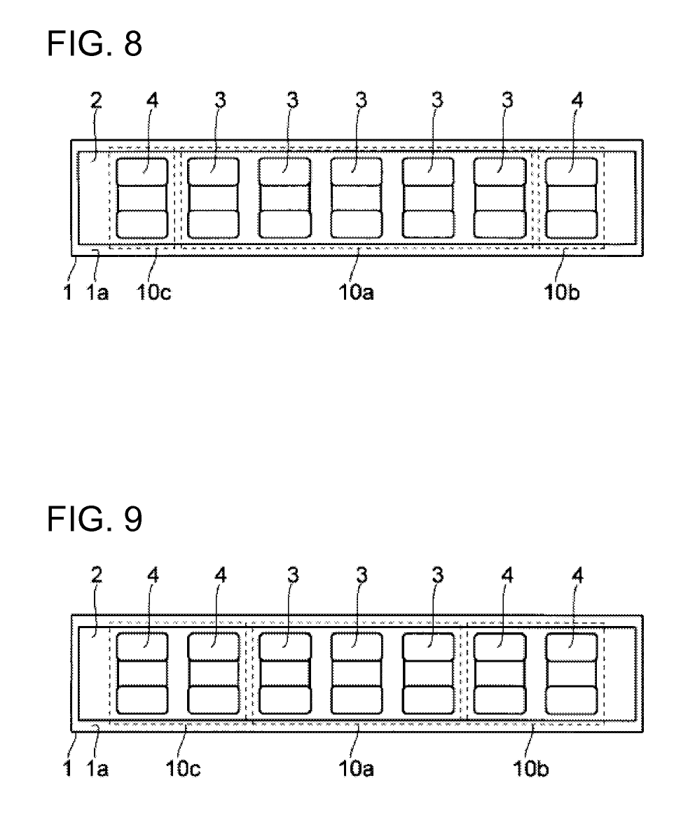

Moreover, with the aforementioned configuration of the first embodiment, even if three or more SMDs 3 are disposed in the SMD mounting region 10a as shown in FIG. 8, effects similar to those of the first embodiment can be obtained.

In addition, in the aforementioned configuration of the first embodiment, if two or more dummy components 4 are disposed in each of the dummy component mounting regions 10b and 10c as shown in FIG. 9, the positional shifting of the SMDs 3 in horizontal directions can be suppressed even further.

Next, an experiment conducted in order to confirm the aforementioned effects of the first embodiment will be described.

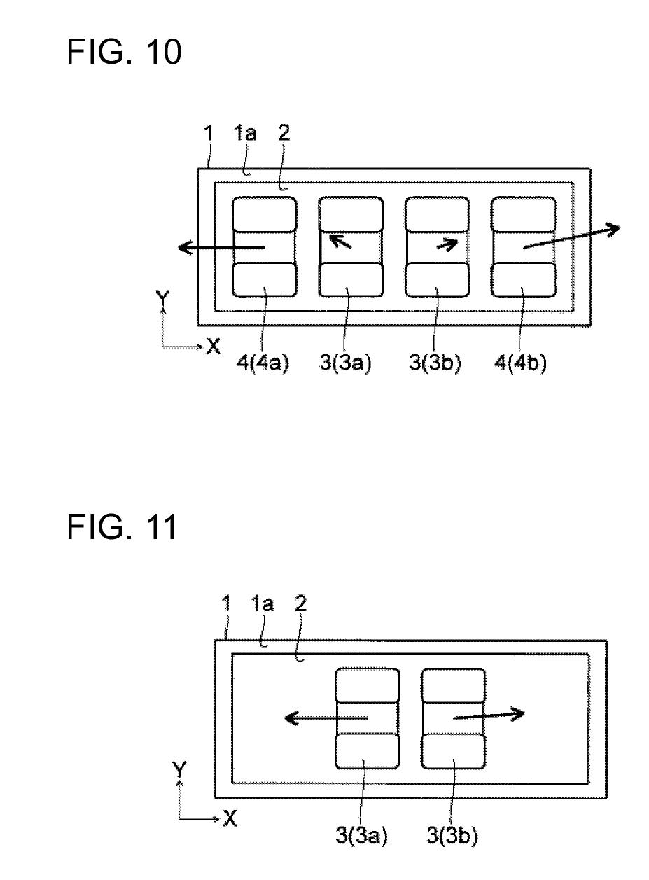

In this confirmation experiment, two types of substrate mounting structure were respectively created using the manufacturing method of the first embodiment and a conventional manufacturing method, with the substrate mounting structure created using the manufacturing method of the first embodiment being taken as a working example (see FIG. 10) while the substrate mounting structure manufactured using a conventional manufacturing method being taken as a comparative example (see FIG. 11). Then, the amount of shifting of the SMDs 3 in horizontal directions was measured for each of the working example and comparative example. The results thereof are shown in Table 1 (working example) and Table 2 (comparative example) below.

In Table 1 and Table 2 below, the desired mounting position is assumed to be 0 μm. Furthermore, in Table 1 and Table 2 below, among the SMDs 3 shown in each of FIGS. 10 and 11, the SMD 3 on the left side is referred to as SMD 3a, while the SMD 3 on the right side is referred to as SMD 3b. Moreover, in Table 1 below, among the dummy components 4 shown in FIG. 10, the dummy component 4 on the left side is referred to as dummy component 4a, while the dummy component 4 on the right side is referred to as dummy component 4b. Note that the arrows in FIGS. 10 and 11 indicate the amount of shifting of the SMDs 3 and dummy components 4 in horizontal directions.

TABLE 1

| | | Following | |
|---|---|---|---|
| | Initial | thermocompression | |
| | placement | bonding | Shifting |
| | (μm) | (μm) | (μm) |
| Dummy | 0 | −52 | −52 |
| component 4a | | | |
| SMD 3a | 20 | 10 | −10 |
| SMD 3b | 0 | 12 | 12 |
| Dummy | 0 | 52 | 52 |
| component 4b | | | |

TABLE 2

| | | Following | |
|---|---|---|---|
| | Initial | thermocompression | |
| | placement | bonding | Shifting |
| | (μm) | (μm) | (μm) |
| SMD 3a | 0 | −43 | −43 |
| SMD 3b | 10 | 40 | 30 |

Referring to Table 1 and FIG. 10, in the working example, the positional shifting of the dummy component 4a occurred 52 μm to the left side from the initially placed state, and the positional shifting of the dummy component 4b occurred 52 μm to the right side from the initially placed state. However, the positional shifting of the SMDs 3a and 3b in horizontal directions became extremely small compared to the positional shifting of the dummy components 4a and 4b in horizontal directions. Specifically, at the initial placement, the SMD 3a was disposed in a position which is shifted 20 μm to the right side from the desired position and returned, at the time of thermocompression bonding, to a position which is shifted 10 μm to the right side from the desired position. That is, the SMD 3a was positionally shifted only 10 μm to the left side from the initially placed state. Furthermore, the SMD 3b was positionally shifted only 12 μm to the right side from the initially placed state.

In contrast, referring to Table 2 and FIG. 11, in the comparative example, the SMD 3a was positionally shifted 43 μm to the left side from the initially placed state. Moreover, the SMD 3b was disposed in a position which is shifted 10 μm to the right side from the desired position at the initial placement and further moved to a position which is shifted 40 μm to the right side from the desired position at the time of thermocompression bonding. That is, the SMD 3b was positionally shifted 30 μm to the right side from the initially placed state. In other words, the positional shifting of the SMDs 3a and 3b in horizontal directions was increased in the comparative example compared to the working example.

From these results, it was possible to confirm that the positional shifting of the SMDs 3 in horizontal directions was suppressed with the configuration of the first embodiment.

Note that in the confirmation experiment described above, size 1005 SMDs were used, and the interspace between adjacent SMDs was set at 0.3 mm. Then, thermocompression bonding was performed with a force of 400N by means of a pressing member composed of rubber (hardness: 80).

### Second Embodiment

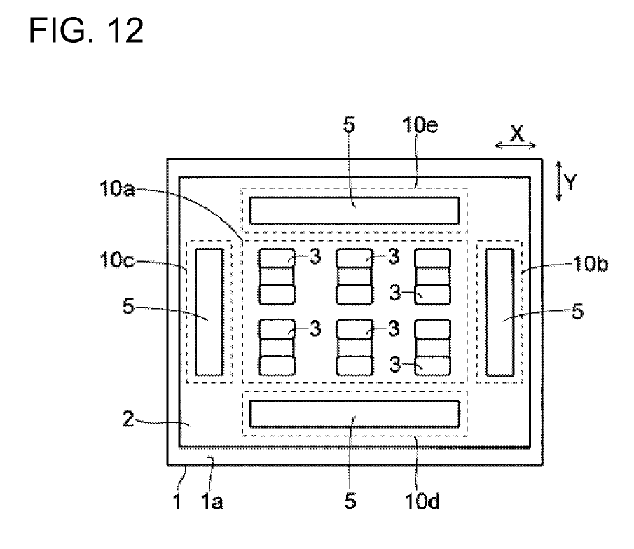

The substrate mounting structure according to a second embodiment will be described below with reference to FIG. 12.

In this second embodiment, in the aforementioned configuration of the first embodiment, a plurality of (e.g., six) SMDs 3 are mounted in the SMD mounting region 10a on the surface 1a of the glass substrate 1, with the plurality of SMDs 3 being arranged in a matrix (in the X direction and Y direction). Then, a plurality of dummy components 5 are mounted on the surface 1a of the glass substrate 1 in prescribed regions thereof so as to surround from four directions a collected body containing the plurality of SMDs 3.

Specifically, in the second embodiment, a region adjacent to one side of the SMD mounting region 10a in the X direction and a region on the other side thereof respectively constitute dummy component mounting regions 10b and 10c, and a region adjacent to one side of the SMD mounting region 10a in the Y direction and a region on the other side thereof also constitute dummy component mounting regions 10d and 10e, respectively. Then, one dummy component 5 is disposed in each of the dummy component mounting regions 10b to 10e. Note that the dummy components 5 are one example of the “prescribed objects” of the present invention.

Incidentally, in this embodiment, the length in the Y direction of the dummy components 5 respectively disposed in the dummy component mounting regions 10b and 10c is set at a length equal to or longer than the length from the outer end of the SMDs 3 located at one end in the Y direction to the outer end of the SMDs 3 located at the other end. Furthermore, the length in the X direction of the dummy components 5 respectively disposed in the dummy component mounting regions 10d and 10e is set at a length equal to or longer than the length from the outer end of the SMDs 3 located at one end in the X direction to the outer end of the SMDs 3 located at the other end. Moreover, the height of the dummy components 5 (the amount of protrusion from the surface 1a of the glass substrate 1) is set at 1 mm or more and also within ±0.3 mm of the height of the SMDs 3 (the amount of protrusion from the surface 1a of the glass substrate 1).

In the second embodiment, by adopting the configuration as described above, in cases where a plurality of SMDs 3 are arranged in a matrix (in the X direction and Y direction), the positional shifting of the plurality of SMDs 3 in the X direction can be suppressed, and the positional shifting of the plurality of SMDs 3 in the Y direction can also be suppressed.

In addition, in the second embodiment, by using the dummy components 5 that are set to have dimensions as described above, the positional shifting of the plurality of SMDs 3 in horizontal directions can be reliably suppressed.

### Third Embodiment

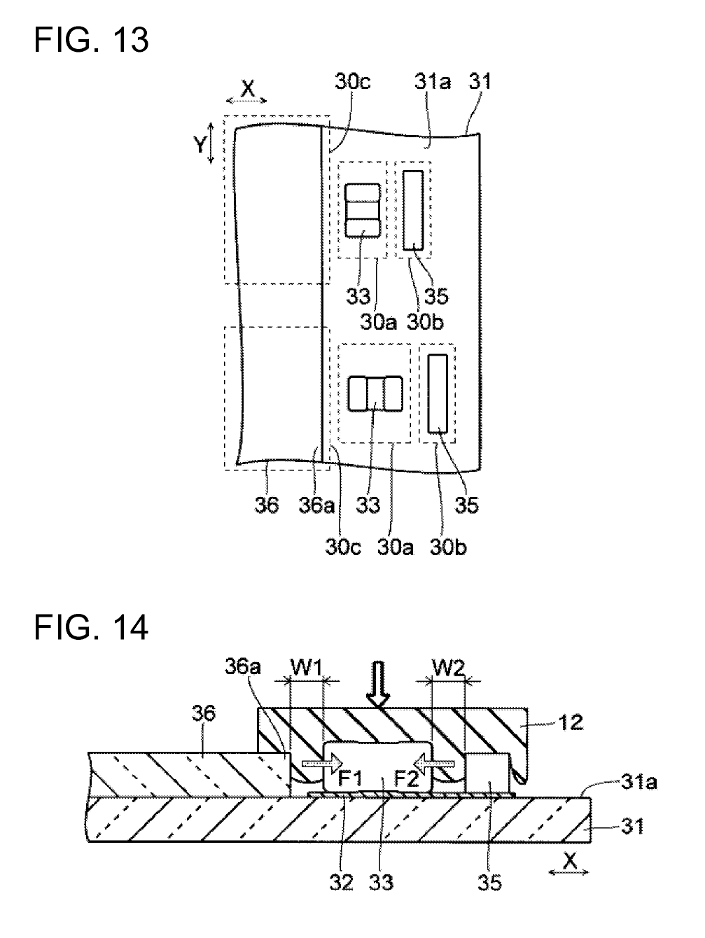

The substrate mounting structure and substrate mounting method according to a third embodiment will be described below with reference to FIGS. 13 and 14.

A glass substrate 31 of the third embodiment is a TFT substrate into which thin-film transistors are fabricated and is used for the liquid crystal panel of a liquid crystal display device (display device). Specifically, another glass substrate (CF substrate into which a color filter is fabricated) 36 is disposed on a surface 31a of this glass substrate 31, and a liquid crystal layer (not illustrated) is sandwiched between the glass substrate 31 and the glass substrate 36. Note that the glass substrate 31 is one example of the “substrate” of the present invention. Furthermore, the glass substrate 36 is one example of the “prescribed object” and “opposite substrate” of the present invention.

Although the glass substrates 31 and 36 are thus superimposed on one another, a portion of the surface 31a of the glass substrate 31 is exposed from the glass substrate 36. Then, SMD mounting regions 30a are provided within the exposed area of the surface 31a of the glass substrate 31, and SMDs 33 are respectively mounted via an ACF 32 (see FIG. 14) in these SMD mounting regions 30a. Note that the SMD mounting regions 30a are one example of the “first region” of the present invention. Moreover, the ACF 32 is one example of the “pressure-bonding adhesive material” of the present invention, and the SMDs 33 are one example of the “electronic components” of the present invention.

Then, in the third embodiment, regions respectively adjacent to one side of the SMD mounting regions 30a in the X direction constitute dummy component mounting regions 30b, and dummy components 35 are respectively mounted via the ACF 32 in these dummy component mounting regions 30b. In addition, no other mounting component is mounted in regions 30c respectively adjacent to the other side of the SMD mounting regions 30a in the X direction, so there is an edge 36a of the glass substrate 36. Therefore, in the third embodiment, a state is created in which each of the SMDs 33 is sandwiched between the glass substrate 36 (edge 36a) and the corresponding dummy component 35. Note that the dummy components 35 are one example of the “prescribed objects” of the present invention. Furthermore, the dummy component mounting regions 30b are one example of the “second region” of the present invention. Moreover, the regions 30c in which the glass substrate 36 (edge 36a) is located are one example of the “third region” of the present invention.

Incidentally, the height of the dummy components 35 (the amount of protrusion from the surface 31a of the glass substrate 31) that are used in this embodiment is set at 0.1 mm or more and also within ±0.3 mm with respect to the height position of the upper surface of the glass substrate 36 (the surface on the opposite side of the surface toward the glass substrate 31). In addition, the length of the dummy components 35 in the Y direction is set so as to be equal to or longer than the lengths of the SMDs 33 in the Y direction. Note that the length of the dummy components 35 in the Y direction may also be shorter than the lengths of the SMDs 33 in the Y direction as long as this length is equal to or longer than a half the lengths of the SMDs 33 in the Y direction.

In the third embodiment, effects similar to those of the first embodiment can be obtained by adopting the configuration as described above.

Specifically, as is shown in FIG. 14, if the respective components are disposed such that the interspace W1 (the distance between the SMDs 33 and the glass substrate 36) and the interspace W2 (the distance between each SMD 33 and the corresponding dummy component 35) are substantially the same, and thermocompression bonding is performed in this state using the elastic body 12 as the pressing member, then the pressing forces (arrow F1) applied to the SMDs 33 in a horizontal direction from the side of the glass substrate 36 and the pressing forces (arrow F2) applied to the SMDs 33 in a horizontal direction from the side of the dummy components 35 become substantially the same. For this reason, it is possible to suppress the positional shifting of the SMDs 33 in horizontal directions.

In the third embodiment, furthermore, the positional shifting of the SMDs 33 in horizontal directions can be reliably suppressed by using the dummy components 35 that are set to have dimensions as described above.

### Fourth Embodiment

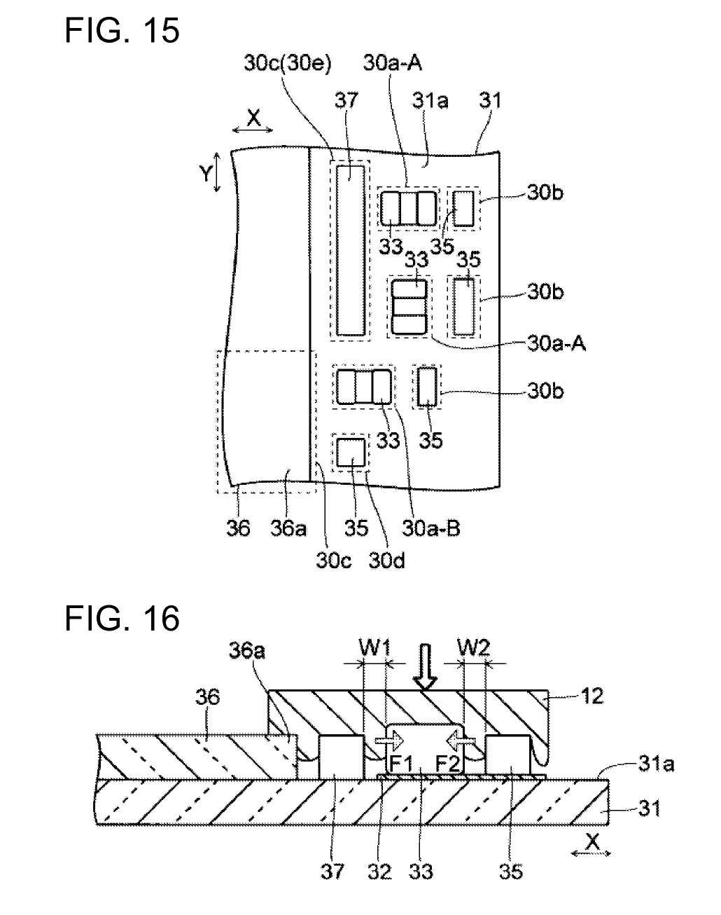

The substrate mounting structure and substrate mounting method according to a fourth embodiment will be described below with reference to FIGS. 15 and 16.

In this fourth embodiment, in the aforementioned configuration of the third embodiment, focusing attention on the SMD mounting regions 30a to which the reference character A is added, dummy components 35 are respectively disposed in dummy component mounting regions 30b which are regions respectively adjacent to one side of the SMD mounting regions 30a-A in the X direction, while an IC component (electronic component other than the SMDs 33) 37 is disposed in a region 30c adjacent to the other side of the SMD mounting regions 30a-A in the X direction. That is, the SMDs 33 disposed in the SMD mounting regions 30a-A are in a state of being sandwiched between the dummy components 35 and the IC component 37. Note that the IC component 37 is one example of the “prescribed object” of the present invention.

Moreover, focusing attention on the SMD mounting region 30a to which the reference character B is added, the SMD 33 disposed in this SMD mounting region 30a-B is in a state in which this SMD 33 is sandwiched in the X direction between the glass substrate 36 (edge 36a) and a dummy component 35 and sandwiched in the Y direction between the IC component 37 and a dummy component 35. Specifically, a dummy component 35 is disposed in a region (dummy component mounting region) 30b adjacent to one side of the SMD mounting region 30a-B in the X direction, while the glass substrate 36 (edge 36a) is disposed in a region 30c adjacent to the other side of the SMD mounting region 30a-B in the X direction. In addition, a dummy component 35 is disposed in a region 30d adjacent to one side of the SMD mounting region 30a-B in the Y direction, while the IC component 37 is disposed in a region 30e adjacent to the other side of the SMD mounting region 30a-B in the Y direction.

The remaining configuration of the fourth embodiment is the same as that of the third embodiment, so a description thereof is omitted.

In the fourth embodiment, effects similar to those of the first embodiment can be obtained by adopting the aforementioned configuration.

Specifically, looking at the SMDs 33 disposed in the SMD mounting regions 30a-A, during the thermocompression bonding step using the elastic body 12 as the pressing member as shown in FIG. 16, loss of the balance of the pressing forces (arrows F1 and F2) applied to the SMDs 33 from horizontal directions is suppressed, so the positional shifting of the SMDs 33 in horizontal directions does not occur easily. Furthermore, the same is true for the SMD 33 (see FIG. 15) disposed in the SMD mounting region 30a-B.

Note that during this thermocompression bonding step, the respective interspaces W1 between the SMDs 33 disposed in the SMD mounting regions 30a-A and the IC component 37 and the respective interspaces W2 between these SMDs 33 and the corresponding dummy components 35 in the X direction are set to be substantially the same. Moreover, the interspace between the SMD 33 disposed in the SMD mounting region 30a-B and the glass substrate 36 and the interspace between this SMD 33 and the corresponding dummy component 35 in the X direction are set to be substantially the same, and the interspace between the SMD 33 disposed in the SMD mounting region 30a-B and the IC component 37 and the interspace between this SMD 33 and the corresponding dummy component 35 in the Y direction are set to be substantially the same.

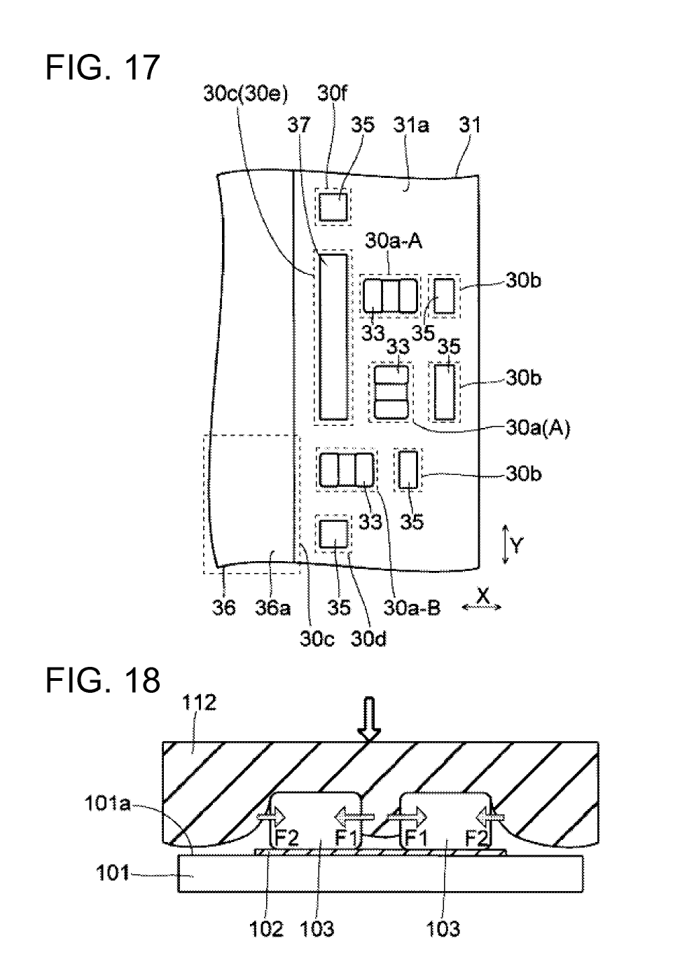

Here, in the aforementioned configuration of the fourth embodiment, as is shown in FIG. 17, an additional dummy component 35 may also be disposed in a prescribed region 30f that is adjacent in the Y direction to the region 30c (30e) in which the IC component 37 is disposed (this prescribed region 30f being a region on the side opposite from the side of the SMD 33). By doing so, the positional shifting of the IC component 37 in horizontal directions can also be suppressed in cases where the SMDs 33 and the IC component 37 are mounted all at once.

The embodiments disclosed herein should be considered as exemplification and not as restrictive in any respect. The scope of the present invention is indicated not by the aforementioned description of the embodiments, but by the scope of the claims, and shall include all modifications with meanings equivalent to those of the scope of the claims and within the scope thereof.

For instance, an ACF was used in the aforementioned embodiments, but the present invention is not limited to this; an NCF (Non-Conductive Film) may also be used, or a pressure-bonding adhesive material other than these may also be used.

In addition, in the aforementioned embodiments, the pressing member (elastic body) was heated during thermocompression bonding, but the present invention is not limited to this; it would also be possible to apply heat from the substrate side.

Furthermore, a state is also created in which SMDs are sandwiched only by components other than dummy components.

### DESCRIPTION OF REFERENCE CHARACTERS

1, 31 glass substrate (substrate)
1a, 31a surface
2, 32 ACF (pressure-bonding adhesive material)
3, 33 SMD (electronic component)
4, 5, 35 dummy component (prescribed object)
10a, 30a SMD mounting region (first region)
10b, 30b dummy component mounting region (second region)
10c dummy component mounting region (third region)
12 elastic body (pressing member)
30c region (third region)
36 glass substrate (prescribed object, opposite substrate)
37 IC component (prescribed object)

1. A substrate mounting structure comprising:
a substrate;
a pressure-bonding adhesive material disposed on a surface of said substrate; and
an electronic component mounted on the surface of said substrate via said pressure-bonding adhesive material and disposed in a first region of a surface area of said substrate,
wherein prescribed objects are respectively disposed in a second region adjacent to one side of said first region and in a third region adjacent to the other side of said first region which is opposite from said one side so that said electronic component is sandwiched by said prescribed objects.

2. The substrate mounting structure according to claim 1, wherein at least said prescribed object disposed in said second region is a dummy component.

3. The substrate mounting structure according to claim 1, wherein said prescribed object disposed in said third region is a dummy component.

4. The substrate mounting structure according to claim 1, wherein said prescribed object disposed in said third region is an electronic component different from said electronic component disposed in said first region.

5. The substrate mounting structure according to claim 1, further comprising an opposite substrate disposed on the surface of said substrate so as to face said substrate, and
said prescribed object disposed in said third region is said opposite substrate.

6. The substrate mounting structure according to claim 1, wherein said electronic component includes a plurality of electronic components, and when among directions parallel to the surface of said substrate, a direction from the side of said second region toward said third region is taken as a first direction, said plurality of electronic components are arranged in said first region along said first direction.

7. The substrate mounting structure according to claim 6, wherein when among directions parallel to the surface of said substrate a direction perpendicular to said first direction is taken as a second direction, said plurality of electronic components are arranged in said first region in a matrix along said first direction and said second direction.

8. The substrate mounting structure according to claim 7, wherein prescribed objects are further respectively disposed in a pair of regions adjacent to said first region in said second direction.

9. The substrate mounting structure according to claim 1, wherein said pressure-bonding adhesive material is an anisotropic conductive film.

10. A display device comprising the substrate mounting structure according to claim 1.

11. A substrate mounting method, comprising:
preparing a substrate and disposing a pressure-bonding adhesive material on a surface of said substrate;
disposing an electronic component in a first region of a surface area of said substrate via said pressure-bonding adhesive material; and
thermocompression bonding said electronic component in said first region by pressing said electronic component toward the surface of said substrate with a pressing member,
wherein the substrate mounting method further comprises, prior to the step of thermocompression bonding said electronic component in said first region, respectively disposing prescribed objects in a second region adjacent to one side of said first region and in a third region adjacent to the other side of said first region which is opposite from said one side, and
wherein when said electronic component is thermocompression-bonded in said first region, said electronic component and said prescribed objects are simultaneously pressed toward the surface of said substrate by said pressing member.

12. The substrate mounting method according to claim 11, wherein at least said prescribed object disposed in said second region is a dummy component.

13. The substrate mounting method according to claim 11, wherein the interspace between said prescribed object disposed in said second region and said electronic component disposed in said first region and the interspace between said prescribed object disposed in said third region and said electronic component disposed in said first region are set to be the same size.
